(19) United States
(12) Patent Application Publication
(10) Pub. No.: US 2010/0140735 A1
(43) Pub. Date: Jun. 10, 2010

(54) NANOSTRUCTURES FOR DISLOCATION BLOCKING IN GROUP II-VI SEMICONDUCTOR DEVICES

(75) Inventors: Ramana BOMMENA, Aurora, IL (US); Sivalingam Sivananthan, Naperville, IL (US); Michael CARMODY, Western Springs, IL (US)

Correspondence Address: Momkus McCluskey, LLC, 1001 Warrenville Road, Suite 500, Lisle, IL, 60532, US

(73) Assignee: EPIR TECHNOLOGIES, INC., Bolingbrook, IL (US)

(21) Appl. No.: 12/331,892

(22) Filed: Dec. 10, 2008

(51) Int. Cl. H01L 29/22; H01L 21/04; H01L 21/762; H01L 29/06

(52) U.S. Cl. 257/506; 438/492; 257/614; 438/429; 257/E29.005; 257/E29.094; 257/E21.04; 257/E21.545; 257/618

(57) ABSTRACT

A compound semiconductor workpiece with reduced defects and greater strength that uses Group II-VI semiconductor nanoislands on a substrate. Additional layers of Group II-VI semiconductor are grown on the nanoislands using MBE until the newly formed layers coalesce to form a uniform layer of a desired thickness. In an alternate embodiment, nanoholes are patterned into a silicon nitride layer to expose an elemental silicon surface of a substrate. Group II-VI semiconductor material is grown in the holes until the layers fill the holes and coalesce to form a uniform layer of a desired thickness. Suitable materials for the substrate include silicon and silicon on insulator materials and cadmium telluride may be used as the Group II-VI semiconductor.

### STATEMENT AS TO RIGHTS IN INVENTIONS MADE UNDER FEDERALLY-SPONSORED RESEARCH AND DEVELOPMENT

The present invention was made with governmental support under Contract No. W911NF-07-C-0083 awarded by the United States Army. The government has certain rights in the present invention.

### BACKGROUND OF THE INVENTION

Mercury cadmium telluride (MCT or HgₓCd₁₋ₓTe, 0<x<1; hereinafter HgCdTe) is the ideal material choice for fabricating infrared photon detectors because of its band gap tunability over a wide range of wavelengths spanning from 1 μm to over 30 μm, covering the short wave infrared (SWIR) to very long wavelength infrared (VLWIR) spectral regions. It is usually grown on CdₓZn₁₋ₓTe (hereinafter, CdZnTe) or CdTe/Si substrates. Though CdZnTe is better lattice matched to HgCdTe, the size of the CdZnTe substrates is severely constrained by the present growth technology, particularly in the growth of large and uniform bulk boules. The high cost of CdZnTe wafers prevents the large scale commercialization of HgCdTe-based infrared arrays, resulting in their principal use in military and space applications. Moreover, CdZnTe is rather brittle and difficult to handle.

Silicon-based alternative substrates promise superior performance and cost in comparison with CdZnTe and have several advantages. First, Si substrates are transparent in the infrared except very near the 0.9 μm end of the range, permitting back-illuminated arrays. Second, a direct coupling is possible between the Si readout of arrays and the Si substrate, allowing the production of very large arrays with a long-term thermal cycling reliability. Third, by growing HgCdTe heterostructures directly on Si-based read-out integrated circuits, one could ultimately fabricate truly monolithically integrated arrays.

There are, however, certain limitations of heteroepitaxy that limit progress in HgCdTe molecular beam epitaxy (MBE) growth on CdTe/Si substrates. To grow high quality HgCdTe, the first step is to grow a high quality CdTe seed layer on silicon. There is a 19.3% lattice mismatch between CdTe and Si that gives rise to a great deal of strain in the heteroepitaxial system. As a result, a large number of threading dislocations form at the heterointerface, which propagate into the CdTe epilayer. These dislocations subsequently propagate into the HgCdTe layer grown on top of the CdTe layer and play a significant role in limiting HgCdTe device performance, especially in the long wavelength infrared (LWIR) and VLWIR regions. Many research and development groups have mounted significant efforts over the past 20 years to reduce the dislocation density in the CdTe epilayers, yet it remains in the low 10⁵/cm². The technique of using a ZnTe buffer layer between the silicon substrate and the CdTe epilayer has resulted in some improvements. However, the defect density in the subsequently grown HgCdTe layer remains higher than that of epilayers grown on CdZnTe substrates. Selective area epitaxy is another technique that has been applied to mitigate strain-related defects, but no significant success has been achieved because of the macro scale patterned features explored in the epitaxial process.

Thus, because of the high suitability of HgCdTe in infrared detectors and the difficulties in producing high quality, durable semiconductors containing HgCdTe layers, there is a need for a new method of and structures for joining these layers to more robust, less expensive materials.

### SUMMARY OF THE INVENTION

The present invention relates to workpieces and methods of forming workpieces that join substrates to at least one Group II-VI semiconductor layer, resulting lower defect densities and increased durability of the semiconductor device.

According to one aspect of the invention, the inventors teach a method of fabricating a compound semiconductor workpiece that comprises providing at least one substrate material from other than a Group II-VI semiconductor, growing a Group II-VI semiconductor seed layer above the substrate, depositing a photoresist layer on the Group II-VI seed layer, and patterning a plurality of islands having a pitch in the range of 100 to 1000 nm into the photoresist layer. The islands are etched into the Group II-VI seed layer to create Group II-VI semiconductor islands. The substrate and islands may then cleaned and at least one additional Group II-VI semiconductor layer is selectively formed on the Group II-VI semiconductor islands.

Preferably, the islands coalesce to form a uniform layer with reduced dislocations. More preferably, the Group II-VI semiconductor comprises CdTe.

According to another aspect of the invention, the inventors teach a method of fabricating a compound semiconductor workpiece that comprises providing at least one substrate made from other than Group II-VI material, forming at least one antireflective coating onto the substrate, forming a photoresist layer above the substrate, and patterning the photoresist layer to leave spaced-apart islands of photoresist on the antireflective coating, the islands having a pitch in the range of about 100 nm to about 1000 nm. The antireflective coating and substrate are etched to leave islands or pillars of substrate and antireflective coating, each island having a lower end proximate to the substrate and an upper end remote from the substrate. The substrate may be cleaned and at least one Group II-VI semiconductor layer is selectively deposited on the islands. The growth process may be permitted to continue so the islands coalesce to form a uniform layer.

More preferably, the step of depositing at least one Group II-VI semiconductor layer on the islands comprises forming a Group II-VI nucleation layer at the highest nucleation temperature for the Group II-VI semiconductor on silicon, increasing the first temperature to a second temperature above the highest nucleation temperature for the Group II-VI semiconductor on silicon, thereby desorbing portions of the nucleation layer, decreasing the second temperature to a third temperature below the highest nucleation temperature of the Group II-VI semiconductor on the Group II-VI seed layer, but above the highest nucleation temperature for the Group II-VI semiconductor on silicon, and selectively forming Group II-VI semiconductor on the islands.

According to another aspect of the invention, the inventors teach a compound semiconductor workpiece that includes at least one substrate material made from a material other than a Group II-VI semiconductor, a plurality of spaced-apart islands having a pitch of from approximately 100 nm to approximately 1000 nm formed from a Group II-VI semiconductor seed layer, each island having a lower end proximate to the substrate and an upper end remote from the substrate, and at least one additional Group II-VI semiconductor layer formed only on the upper end of the islands. Preferably, the substrate is silicon on insulator (SOI).

In another aspect of the invention, the inventors teach a compound semiconductor workpiece comprising a substrate made of material other than Group II-VI semiconductor material and a monolithic layer of Group II-VI semiconductor material disposed above the substrate where the layer has a predicted dislocation density of less than approximately 5×10⁵/cm².

According to another aspect of the invention, a semiconductor device comprises a substrate made of material other than Group II-VI semiconductor material and a monolithic layer of Group II-VI semiconductor material disposed above the substrate, the layer having a predicted dislocation density of less than approximately 5×10⁵/cm².

According to another aspect of the invention, the inventors teach a method of fabricating a compound semiconductor workpiece comprising providing at least one substrate material having an upper face of elemental silicon, forming at least one silicon nitride layer on the upper face of the substrate, depositing at least one photoresist layer above the silicon nitride layer, and patterning a plurality of holes into the photoresist layer having a pitch in the range of 100 nm to 1000 nm. At least the silicon nitride layer is etched and Group II-VI semiconductor material is filled into at least the plurality of holes.

Preferably, responsive to said step of growing Group II-VI semiconductor material in the holes, the Group II-VI semiconductor material coalesces to form a uniform Group II-VI layer with reduced dislocations.

According to another aspect of the invention, the inventors teach a compound semiconductor workpiece, including at least one substrate material with an elemental silicon face, at least one silicon nitride layer grown on the substrate, a plurality of holes etched into at least the silicon nitride layer having a pitch in the range of 100 to 1000 nm, and at least one Group II-VI semiconductor layer formed in the plurality of holes. The holes may be etched into one or more moiré patterns.

Preferably, the semiconductor structure further includes a passivating layer. Even more preferably the structure also includes at least one buffer layer formed to adjoin the Group II-VI semiconductor.

### BRIEF DESCRIPTION OF THE DRAWINGS

Further aspects of the invention and their advantages can be discerned in the following detailed description, in which like characters denote like parts and in which:

FIG. 1 is a first schematic block diagram showing a first method of fabricating a semiconductor workpiece;

FIG. 2 is a series of successive highly magnified schematic isometric views of a workpiece showing a process for fabrication of nanoislands followed by epitaxial lateral overgrowth;

FIGS. 3A and 3B show perspective SEM images of 500 nm pitch grating (left) and 360 nm pitch grating (right);

FIG. 4 is a photomicrograph showing a highly magnified cross-sectional SEM image of nanoislands fabricated without an anti-reflective coating (ARC);

FIG. 5 is a highly magnified cross-sectional SEM image showing nanoislands fabricated with an ARC;

FIG. 6 is a plan view of a workpiece showing developed photoresist after the post exposure bake;

FIGS. 7A and 7B are microphotographs showing top and perspective views of CdTe islands on silicon;

FIG. 8 is a microphotograph taken from the top of a nanoisland array, showing selective layer deposition after etching;

FIGS. 9A and 9B are microphotographs showing top views of partially coalesced CdTe;

FIG. 10 is an AFM image of a nanopatterned CdTe buffer layer substrate with the section analysis;

FIG. 11 is an AFM image of selectively grown CdTe on the nanopatterned CdTe buffer layer shown in FIG. 10, accompanied by a section analysis showing the thickness of the film;

FIG. 12 is an AFM image of regrown CdTe showing regions of lateral epitaxial overgrowth;

FIG. 13 is a schematic block diagram showing a second method of fabricating a semiconductor workpiece;

FIGS. 14C and 14D show a series of schematic isometric views of a workpiece showing a process for fabrication of nanoislands followed by epitaxial overgrowth;

FIGS. 15A and 15B show plan view SEM images of CdTe selectively grown on nanopatterned SOI substrates;

FIG. 16 is an AFM section analysis of a sample of CdTe selectively grown on SOI having 1 μm pitch nanopillars;

FIG. 17 is an x-ray diffraction graph (intensity v. 2θ) of selectively CdTe grown on 1 micron pitch nanopatterned SOL

FIGS. 18A and 18B are plan view photomicrographs of an array of CdTe nanoislands on SOI showing coalescence of CdTe;

FIG. 19 is a block diagram showing a method of fabricating a semiconductor workpiece;

FIG. 20A (top left) is a schematic diagram of hexagonal moirés;

FIG. 20B (top right) is a photomicrograph of hexagonal moirés etched into a substrate;

FIG. 20C (bottom left) is a photomicrograph of GaN layers selectively grown in hexagonal moirés;

FIG. 20D (bottom right) is a photomicrograph of GaN layers that have coalesced into crack-free layers; and

FIG. 21 is a schematic of interferometric lithography set up.

### DETAILED DESCRIPTION

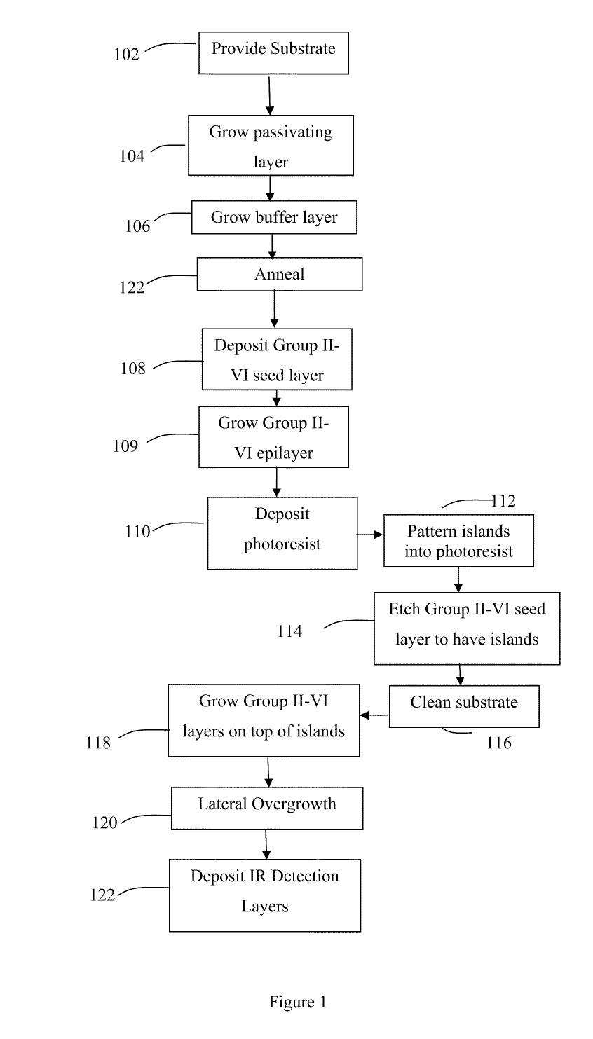

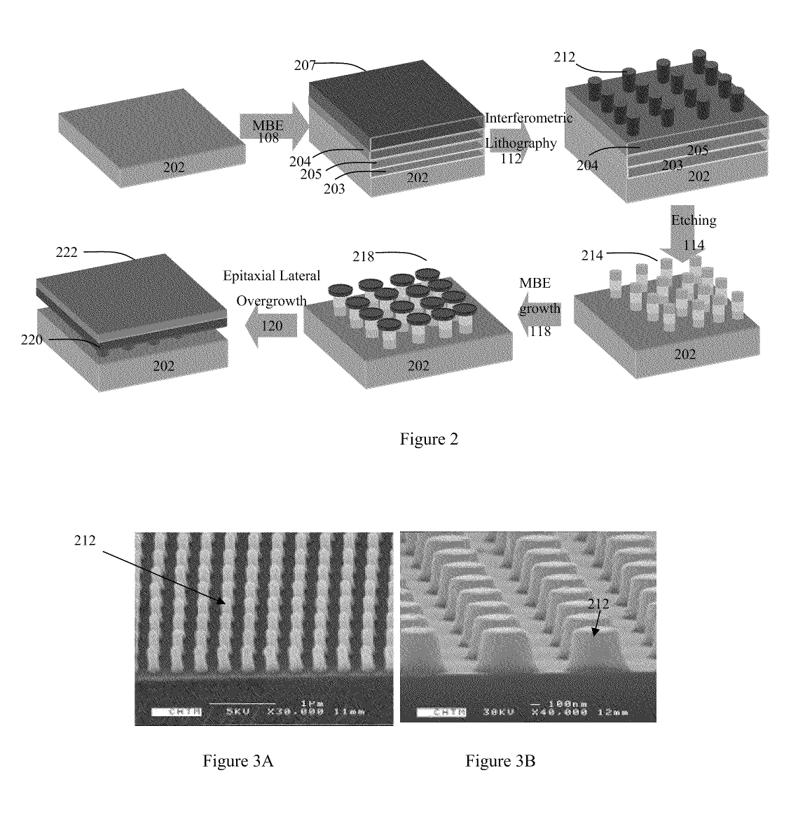

In the following discussion, reference is made to FIGS. 1 and 2. In a first aspect of the invention, the inventors disclose a method of fabricating a Group II-VI semiconductor structure with a reduced number of dislocations comprising providing (step 102, FIG. 1) at least one substrate material 202 (FIG. 2) made from material other than Group II-VI semiconductor. Suitable substrates include, but are not limited to, silicon, sapphire, and silicon on insulator (SOI) substrates. A monolithic seed layer 204 of Group II-VI semiconductor material is grown above the substrate 202.

Prior to growth of the seed layer, silicon (211) wafers are subjected to an ex-situ RCA cleaning procedure to obtain clean atomic surfaces for performing MBE growth. The RCA procedure has three major sequential steps: performing an organic clean by removing insoluble organic contaminants with a 5:1:1 H₂O:H₂O₂:NH₄OH solution, oxide stripping by removing a thin silicon dioxide layer using a diluted H₂O:HF solution where metallic contaminants may accumulated as a result of the above step, and ionic cleaning by removing ionic and heavy metal atomic contaminants using a solution of 6:1:1 H₂O:H₂O₂:HCl.

Following the ex-situ cleaning, each silicon wafer is loaded into an introduction chamber and transferred into a preparation chamber where it is prebaked for several hours. The sample is then transferred into the growth chamber under high vacuum and the temperature is ramped to approximately 1050° C. Each sample is left at that temperature for approximately thirty seconds to desorb any oxide on the silicon surface and the samples may then be subjected (step 104) to an arsenic flux while ramping down the temperature to 400° C., leaving a thin passivating layer 203 of arsenic adjacent to the substrate. A thin buffer layer 205, preferably ZnTe, may be grown (step 106) remote from the substrate at 330° C. to preserve the (211) orientation.

This buffer layer 205 is annealed (step 122) at 460° C. for 10 minutes, followed by the growth (step 109) of a CdTe epilayer 204 by molecular beam epitaxy (MBE) at a substrate temperature of 390° C. for approximately 10 hrs. The growth rate of CdTe is approximately 1 μm/hr, which results in a CdTe thickness of approximately 10 μm. Double crystal rocking curve (DCRC) measurements performed on samples made according to this procedure indicated high quality CdTe.

After forming the CdTe epilayer 204, a photoresist layer 207 is deposited (step 110) on the Group II-VI epilayer 204 and baked at 115° C. for 3 minutes. The photoresist is cleaned in acetone for 10 minutes, rinsed in isopropyl alcohol for 5 minutes, rinsed in deionized water for 5 minutes, and blown dry with nitrogen. The substrate is then baked on a contact hot plate at 65° C. for 60 seconds to desorb any moisture. A photoresist adhesion promoter, such as hexamethyl disilane (HMDS), is spun on several samples at 4000 rpm for 30 seconds and the samples are then baked at a temperature of 95° C. for 60 seconds.

A positive photoresist is spun (step 110) onto the samples at 3000 rpm for 30 seconds and had a thickness of 500 nm for these conditions as per the manufacturer's specifications. The samples are baked at 95° C. for 3 minutes and transferred to the interferometric lithography lab, where the equipment is set up to pattern two-dimensional features of a desired size, shape, and pitch.

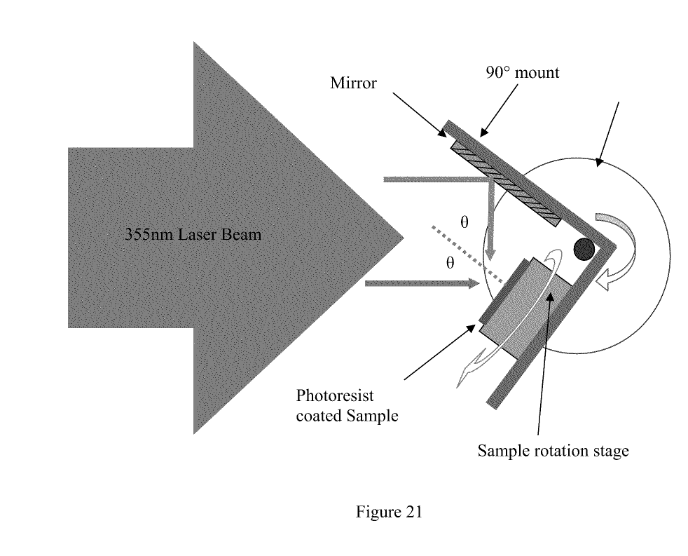

Interferometric lithography (step 112) is a mask-less and relatively simple method of forming periodic arrays of sub-micron structures on the surface of a substrate that uses interference between coherent laser beams to define a pattern. See FIG. 21. There is a large parameter space that needs to be explored when fabricating nanoscale features: the feature density and dimensions, pattern symmetry, the underlying layer structure and also the grouping of the nanoelements. Interferometric lithography is a unique approach that in principle allows all these requirements to be controlled. In one set of experiments, the features were set up on a 500 nm pitch with laser emission at 60 Hz and 50 mJ energy. The samples are exposed in one direction and rotated 90° for a second exposure. After exposure, they are baked at 110° C. for 60 seconds and then developed in a developer to pattern 112 the features 212.

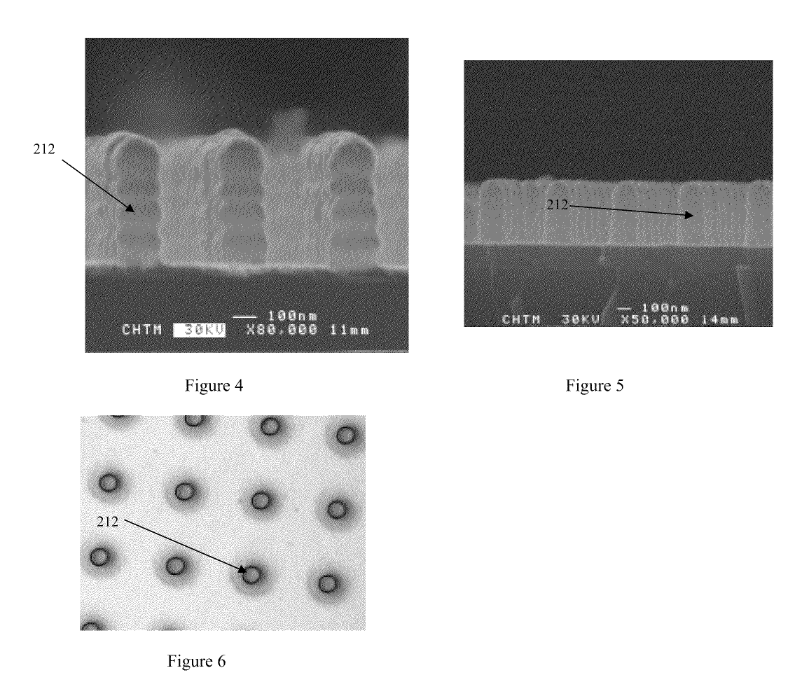

We have obtained very uniform 2-dimensional islands 212 of photoresist on a 500 nm pitch on the thin CdTe seed layers, as seen from the perspective view SEM images in FIGS. 3A and 3B. We further characterized these features with cross-sectional SEM to evaluate the lateral dimensions, sidewall profile and the morphology of the photoresist. A cross-sectional SEM image is shown in FIG. 4.

The cross-sectional SEM image shows approximately 200 nm diameter photoresist islands 212 (approximately 450 nm high) on a 500 nm pitch. Expected pitches may range from approximately 100 nm to approximately 1000 nm and heights of the photoresist islands may range from 15 to approximately 500 nanometers. The sidewalls of the islands are serrated as a consequence of standing wave patterns that are generated with the interference between the incident and the reflected beam from the surface of the sample underneath the photoresist layer. An antireflective coating layer is usually used to absorb the incident laser beam to avoid the standing wave patterns. Although this is desirable to obtain good sidewall profiles, during the pattern transfer stage one must etch the antireflective coating and then etch the underlying layer. We have explored the use of antireflective coating on a few test pieces of CdTe/Si to fabricate two-dimensional islands. Cross-sectional SEM images obtained from the use of antireflective coating underneath the photoresist are shown in FIG. 5.

The SEM image in FIG. 5 shows that the standing wave patterns are reduced with the use of an antireflective coating on the samples. The property of the antireflective coating that reduces the standing wave patterns is its low refractive index compared to the surface underneath, hence it doesn't allow the reflected wave from the surface to transmit through. Generally, it is very difficult to fabricate nanoscale patterns in photoresist on a silicon surface without an antireflective coating but CdTe tends to act as an antireflective coating because the refractive index of CdTe is smaller than silicon, thereby reducing the standing wave patterns.

We have successfully fabricated 150-200 nm diameter islands of photoresist on CdTe seed layers using interferometric lithography. We believe this is the first attempt to fabricate nanoscale features on CdTe epilayers grown on silicon (211) substrates. Islands 212 with diameters from approximately 20 nm to approximately 500 nm may be used.

Returning to FIGS. 1 and 2, to effectively transfer the nanoscale features into the CdTe epilayer 204, a reliable etch technique with good control over the etch rate, surface morphology and the sidewall profile is required. Wet etching with Br/methanol and Br/lactic acid is a commonly used approach for etching CdTe. However, wet etching is isotropic in nature and limits the feature dimensions that can be etched due to the undercut involved with the process. This requires a dry etching technique that can provide the required resolution of etch to the sub micron dimensions.

Dry etch technology offers the ability to produce anisotropic etch profiles, resulting in more photodiodes per unit area. In addition to an anisotropic nature that is critical for accurate dimensional control, dry etching provides greater uniformity, smaller amounts of hazardous waste and in situ vacuum processing capability. Dry etching of CdTe with CH₄/H₂ has been reported and the same chemistry is also being used for the dry etch of HgCdTe. Different dry etch mechanisms have been developed so far for HgCdTe and there is still extensive research going on to develop the best possible technique. Plasma etching with H₂, Ar and CH₄ has been reported as the extensively used etch chemistry for HgCdTe. Several plasma etch techniques such as reactive ion etching (RIE), electron cyclotron resonance (ECR) and inductively coupled plasma etching (ICP) have been explored for dry etching of II-VI compounds.

Inductively coupled plasma (ICP) etching is a technique that provides high-density plasma at low pressure. The ICP technique has been reported to result in superior control over etching large area wafers and reproducibility and involves coupling radio frequency (RF) power into a vacuum chamber from an inductive coil while biasing a stage with an independent RF power. This allows separate control over ion energy and ion density during plasma etching or deposition. In the following example, we present the details of the ICP etch process developed for etching CdTe mesas.

### Example 1

A 3-inch Si (211) wafer with approximately 5 μm CdTe grown by MBE was spun with photoresist SPR 1818 at 3000 rpm for 30 seconds and baked at 115° C. for 3 minutes. This wafer was then diced into 20 mm×20 mm pieces and the photoresist was stripped away in acetone (this photoresist layer was used to protect the CdTe epilayer from being damaged during the dicing of the wafer). The 20 mm×20 mm samples were then spun with a negative photoresist SU-8 @ 3000 rpm for 30 seconds and were subjected two different baking steps: 60 seconds @ 65° C. and 120 seconds @ 95° C. An iron oxide mask with a 320×256 array format having pixel regions of 5 μm on a 30 μm pitch was used on a MJB-3 mask aligner to perform contact lithography. The exposures were performed for 11 seconds and the samples were then baked in two steps: 60 seconds @ 65° C. and 120 seconds @ 95° C. These were then developed for 12 seconds in the SU-8 developer solution.

Optical microscope images of the photoresist are shown in FIG. 6, which shows rounded mesas 212 due to a short over-developing after the post exposure bake. This is desirable in this case because it results in cylindrical photoresist pillars, which will finally lead to circular CdTe features after etching. The samples were rinsed in isopropyl alcohol after developing because the negative photoresist used is sensitive to aqueous solutions.

ICP etching (step 114) of CdTe was performed on a Oxford instruments Plasmalab 100 ICP chamber which has six gas lines CH₄, H₂, N₂, O₂, Ar and SF₆, a temperature controller with helium back flow, a custom gas ring to feed gases directly over a 3-inch wafer, and two separate power supplies for controlling plasma density and ion energy. Process development was performed on various samples with various etch process parameters, source gas flow rates, RF power, ICP power and chamber pressure, to optimize the etch conditions for reproducibility.

Feedback for tuning the etch process (step 114) was obtained from profilometry, optical microscopy and SEM. CH₄ and Ar were used as source gases in the plasma chamber with flow rates in the range 0-15 sccm and 0-20 sccm respectively while RF power and ICP power in the range 0-30 Watts and 0-750 Watts, respectively, were used. A chamber pressure of 5 mTorr with a helium back flow of 10 Torr (used to maintain the sample at room temperature in the plasma) was used to maintain an etch rate of approximately 0.22 μm/min. The etch duration was timed to approximately 25 minutes to etch the CdTe layer 204 and layers 207, 205, and 205 down to the silicon substrate 203.

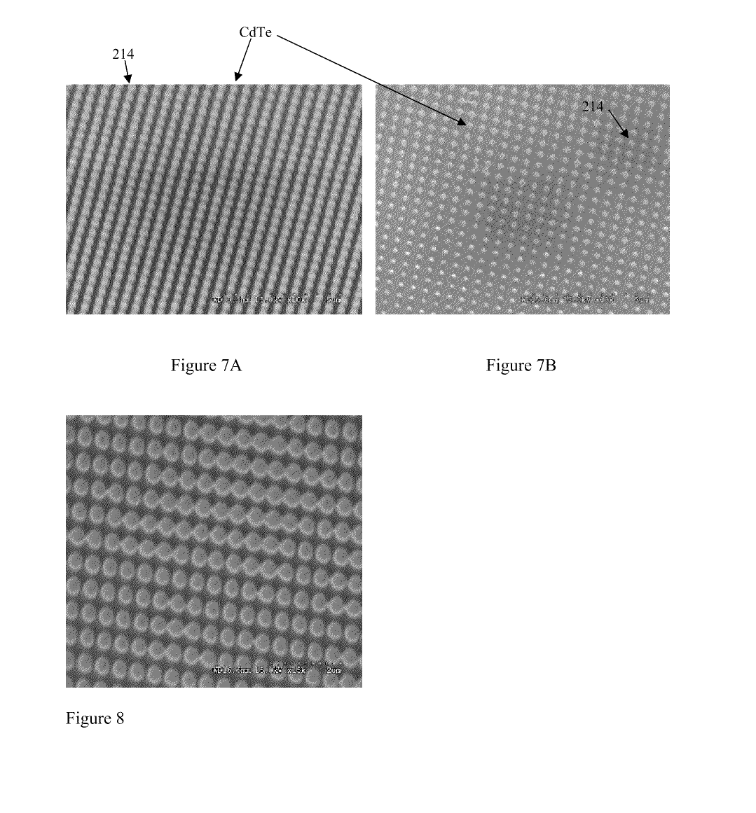

FIGS. 7A and 7B show a plurality of islands 214 in a two dimensional array having lower ends proximate to the substrate and upper ends remote from the substrate. These figures also show a very clean surface 700 after etching, which is indicative of the silicon substrate underneath the CdTe epilayer 204. The sizes of the mesas 214 obtained after etching are comparable to the features on the mask used for photolithography, which indicates good control of the etch process in retaining the feature dimensions. Cross-sectional SEM was performed to characterize the sidewall profile and the etch depth obtained on the samples.

These SEM images show a etch depth of between approximately 50 nm and approximately 300 nm, which is within the wider range of approximately 15 nm to approximately 500 nm. The aspect ratio of the features is 1:1, which is a significant result in etching CdTe with a dry etch process.

We had previously observed that the photoresist had hardened after the etch process and it was difficult to clean from the surface of the CdTe. This could be a potential problem during MBE growth since the carbon associated with the polymer in the photoresist will contaminate the MBE chamber when the sample is loaded into the chamber. Also, surfaces with photoresist residue are not ideal surfaces for the onset of epitaxy. As shown in FIG. 1, it is preferred to clean (step 116) the surface 700 after the etch process using oxygen plasma to strip the resist from the surface. We found that the surfaces were almost completely cleaned of photoresist after 10 minutes of subjecting the etched surfaces to oxygen plasma. SEM was performed on a sample etched with ICP before the photoresist was cleaned and the same sample cleaned with oxygen plasma for 10 minutes to characterize the surfaces after the etch process.

Molecular Beam Epitaxy (MBE) is then used to regrow CdTe on nanopatterned CdTe seed islands 214. In the following example, we present the details of the regrowth of CdTe layers on the islands.

Prior to growth, the samples were subjected to an ex-situ cleaning process (part of step 116) to remove the oxidized CdTe surfaces. We determined that the nanopatterned samples are sensitive to this cleaning process because the usual Br/Methanol etch used for CdTe/Si substrates resulted in nanopillar lift-off. This is due to the high etch rate of the material with this solution. The wet etch process rapidly damaged the substrates through undercutting since the nanopillars are only approximately 200 nm in diameter and of similar thickness. We improved the cleaning process by using a diluted solution of HBr:DI:H₂O₂ (1:50:10) to treat the nanopillar surfaces.

Samples of 10 mm×10 mm size were loaded into the MBE chamber and subjected to an tellurium dioxide desorption process at a temperature of between 260° C. and 400° C. Following desorption, CdTe was grown at a temperature of 510° C.

Reflection high energy electron diffraction (RHEED) analysis from the MBE process shows patterns indicative of single crystal (211) CdTe being present after growth. This shows that single crystal CdTe was regrown 118 on the nanopillars 214. Moreover, (211) is the preferred orientation of the CdTe layer that will be needed for the subsequent growth of HgCdTe.

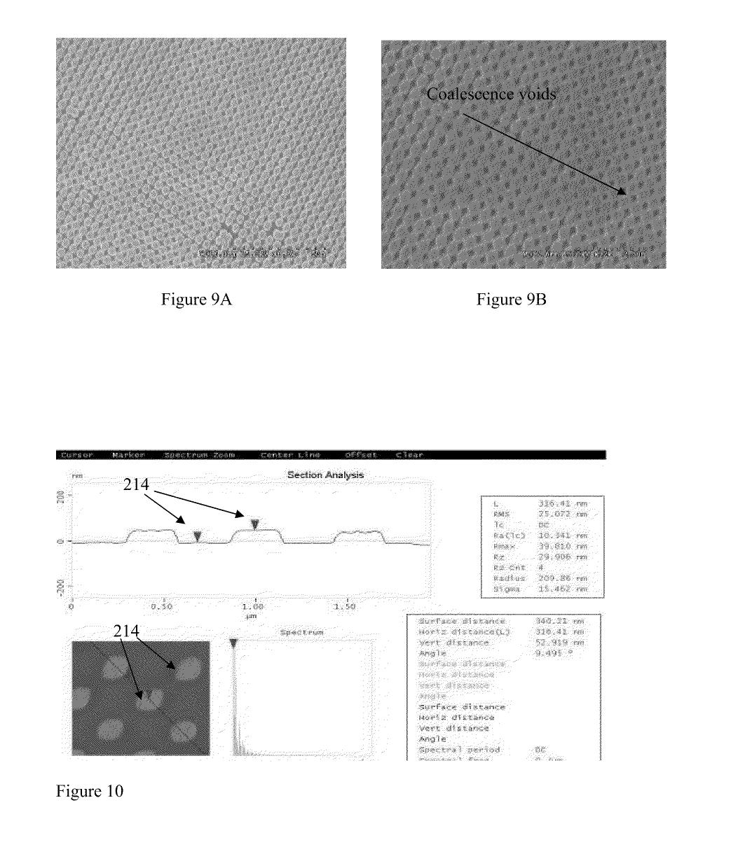

SEM analysis was performed to characterize the regrown layers. FIG. 8 shows that selective CdTe growth was obtained from the regrowth process on the nanopatterned CdTe seed layer samples. Selectivity of the growth process appears to highly homogeneous on the sample, which is important for subsequent epitaxial lateral overgrowth leading to coalescence, as shown in FIGS. 9A and 9B. The high degree of uniformity in the periodic nanoscale features on the samples and the optimization of the MBE growth process have led to the successful selective growth 118 of single crystal CdTe (211) on the nanopatterned CdTe substrates.

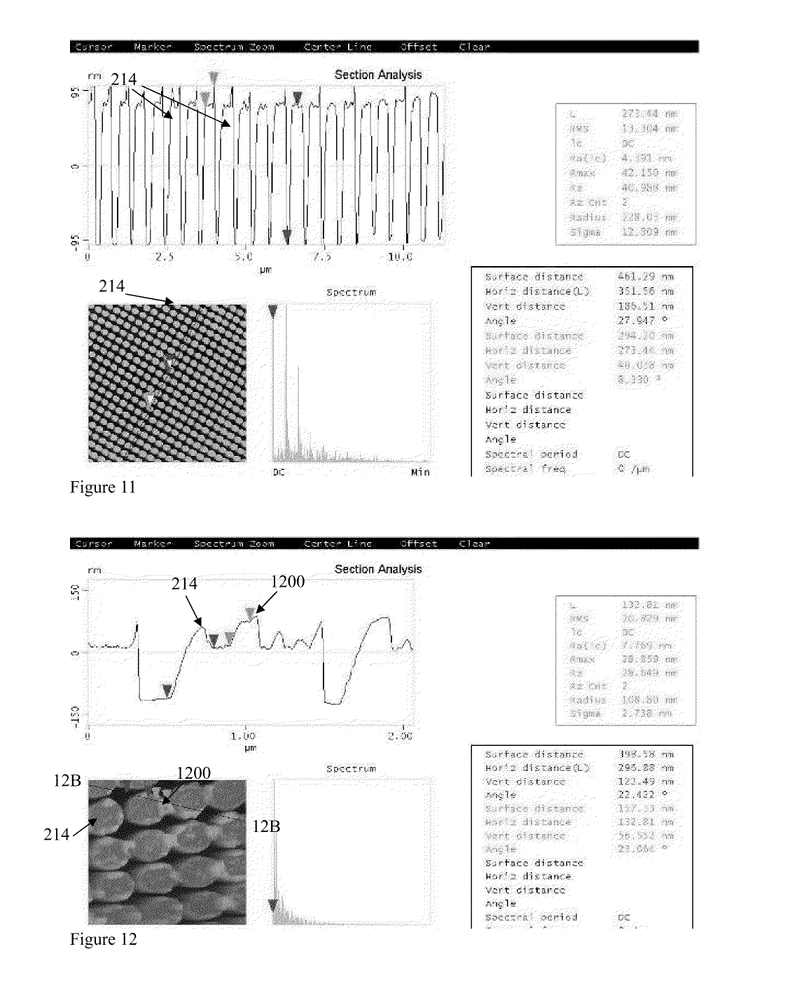

Following the homogeneous selective growth 118 of CdTe on nanopatterned CdTe seed layers, the selective growth of CdTe on nanopatterned CdTe seed layers was accomplished by the MBE growth technique. This is, to our knowledge, the first report of nanoscale selective CdTe growth. Initially, the MBE growth conditions were calibrated to obtain the highest nucleation temperature of CdTe on silicon. Following this, CdTe was regrown on the nanopatterned CdTe seed layers at a temperature slightly higher than the highest nucleation temperature of CdTe. This process enables the nucleation of CdTe only on CdTe. No nucleation was seen on the silicon surface. SEM characterization of the grown samples has shown the selectivity of the growth with an increase in the diameter of the islands as compared to before growth. AFM characterization was performed to characterize the regrown CdTe since it would influence the next stage of the nanopatterned growth, which was the lateral epitaxial overgrowth (LEO) 120. An AFM image of the substrate and nanoislands 212 before the selective growth of CdTe is shown in FIG. 10. The thickness of the CdTe nanopillars 214 before the growth was approximately 53 nm, as indicated by the vertical distance in the line scan analysis of the AFM image shown in FIG. 10.

An AFM image of a selectively grown CdTe sample on the nanopatterned CdTe nanopillars 214 is shown in FIG. 11. The thickness of the CdTe after 15 minutes of MBE regrowth was approximately 186 nm. This corresponds to a growth rate of approximately 1.2-1.4 Å/sec. We did not observe any change in the thickness between the CdTe islands, which indicated that the CdTe grown during the regrowth process was indeed selective.

We observe in FIG. 12 that a ‘nanobridge’ 1200 formed between two CdTe islands 214. The horizontal distance between the two islands 214 joined by bridge 1200 is approximately 132 nm. It should be noted that the size of the islands 214 before growth was approximately 200 nm and the pitch was approximately 500 nm. This corresponds to a separation of approximately 300 nm between the islands before growth. Based on the size of the nanobridge 1200, we see that the islands were almost coalescing at the stage shown in FIG. 12. The increase in diameter has reduced the separation between the islands and the high degree of uniformity in the growth of the islands indicates a path towards coherent coalescence, which was essential to form a complete film on the substrate. AFM measures a vertical island height of approximately 122 nm, but this was probably an underestimate since it is quite possible that the AFM tip is unable to touch the bottom of the substrate due to the small separation between the islands.

Lateral epitaxial overgrowth (step 120) may be allowed to continue until a completely coalesced layer 220 of CdTe results, with fewer dislocations than have been achieved by prior manufacturing techniques. Additionally, other layers and structures may be formed. Finally, one or more infrared detection layers 222, preferably formed of HgCdTe, may be grown 122 on the coalesced CdTe layer. The band gap of these layers may be tuned so they detect wavelengths spanning approximately 1 μm to at least approximately 30 μm, effectively covering the short wave infrared to the very long wave infrared spectral regions.

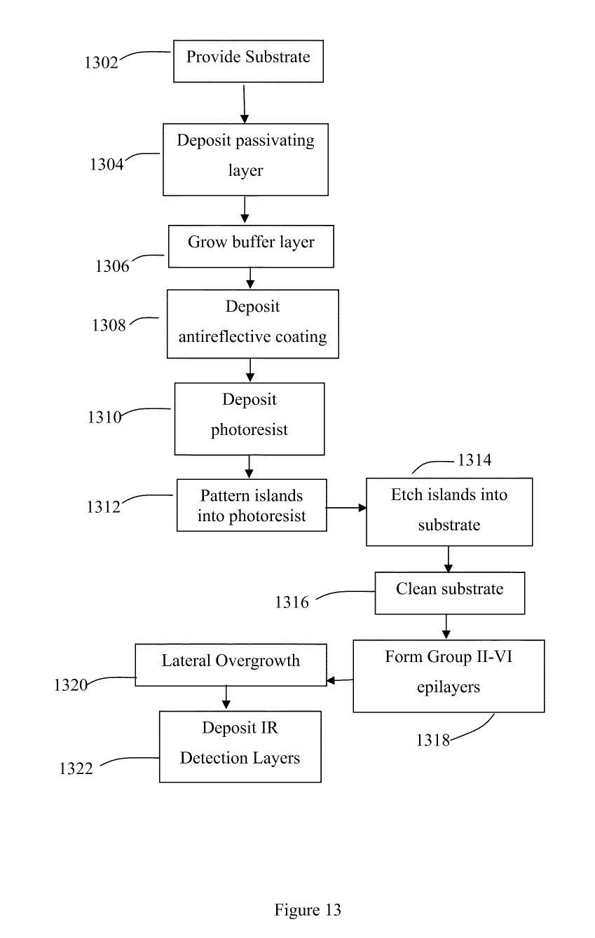

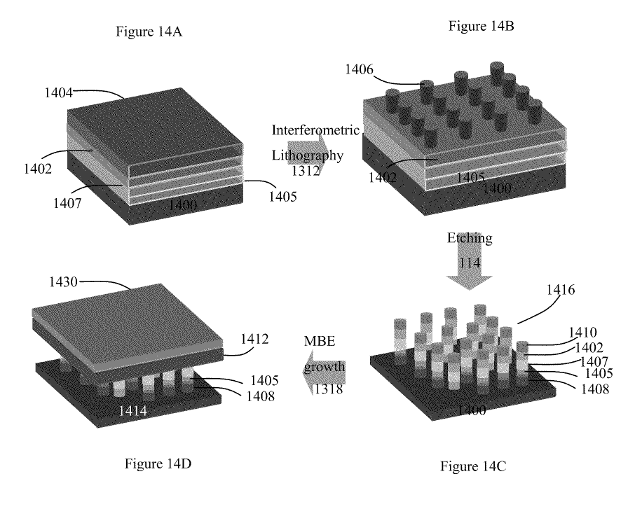

In another embodiment of the invention, the inventors disclose a method of fabricating a Group II-VI semiconductor structure without the use of the monolithic Group II-VI semiconductor seed layer described above. The steps of this method are illustrated in FIG. 13. Schematic sectional views showing different stages in the process are shown in FIGS. 14A-14D.

Suitable substrates have an upper surface of elemental Si, and include silicon and silicon on insulator (SOI) substrates. After choosing (step 1302) the substrate 1400, an antireflective coating (ARC) 1402 is deposited (step 1308) is to and then to deposit (step 1310) a layer of photoresist 1404. The ARC may have a thickness of between approximately 150-160 nm and the photoresist a thickness of approximately 250 nm. Optionally, a passivating layer 1405, preferably of arsenic, and buffer layer 1407, preferably of zinc telluride, may be formed (step 1304 and step 1306) before applying the photoresist layer. The following example describes in detail the procedures used.

### Example 2

SOI substrates 1400 (20 mm×20 mm pieces) were subjected to a chemical rinse in piranha and then deionized water. A layer 1402 of ARC (XHRI-16) was spun (step 1308) on the samples at 4000 rpm for 30 seconds and then hard baked at a temperature of 175° C. for 3 minutes. This process resulted in an ARC thickness of 150 to 160 nm. The bake allowed the ARC 1402 to sustain beam exposure without cracking The ARC 1402 was an organic polymer that serves to avoid standing wave patterns that would otherwise result from the interference between the incident laser beam and the reflected beam from the substrate.

The substrates were cooled for 60 seconds and then spun (step 1308) with a positive photoresist 1404 at 4000 rpm for 30 seconds. Subsequently, they were soft baked at 95° C. for 3 minutes. The SOI samples were exposed to ultraviolet (UV) radiation for 15 sec and then rotated by 90 degrees for a second exposure to obtain 2-D features. Following the UV exposure, the samples were developed (step 1312) in a MF702 developer for 75 seconds. Two-dimensional pillars 1406 (FIG. 14B) in photoresist were obtained from this process with feature dimensions between 100 nm to 1000 nm. Three different pitch (center to center spacing) values of 360 nm, 500 nm and 1000 nm were used for fabricating multiple geometry samples. Other pitches ranging from approximately 100 nm to approximately 1000 nm may be used.

Following the interferometric lithography process (step 1312), reactive ion etching (step 1314) was used to transfer (step 1314) the nanoscale patterns into the substrate 1402 (FIG. 14C). Reactive ion etching (step 1314) offers precise control over the etch process with good anisotropy and selectivity of etch. The samples were then cleaned (step 1316) in piranha solution to strip the ARC 1402 and the photoresist 1404.

After etching and cleaning the substrate, a Group II-VI semiconductor layer, preferably CdTe, is formed 1318 on the nanoscale patterns. Example 3 below provides specific details on the procedures and process conditions.

### Example 3

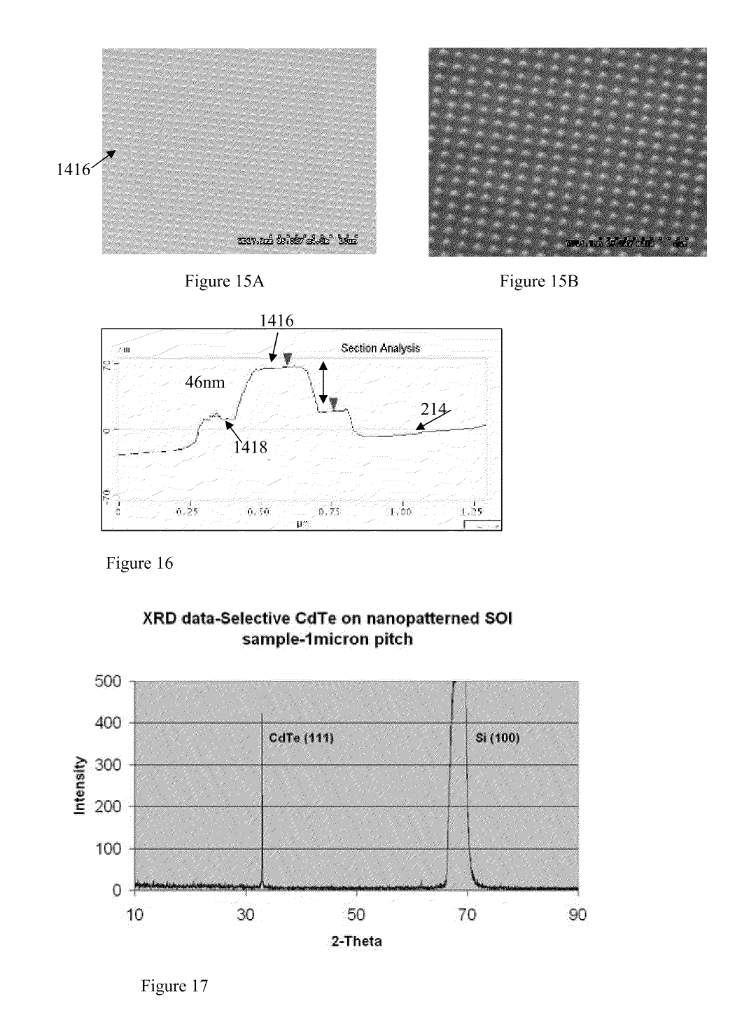

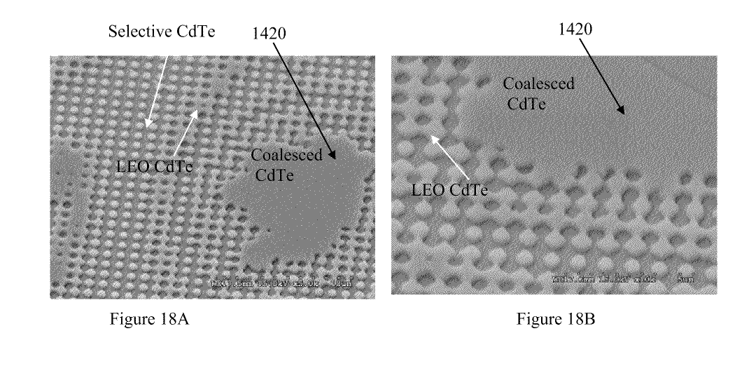

A custom holder suitable for holding 6 pieces of 10 mm×10 mm and 2 pieces of 20 mm×20 mm size was used for the CdTe growth on silicon nanopillars 1408. The samples were subjected to RCA cleaning and blown dry with nitrogen before being loaded into the introduction chamber and transferred into the preparation chamber, where they were prebaked at 500° C. for 8 hours. The samples were then transferred into the growth chamber under high vacuum and the temperature was ramped to 1050° C. The samples were left at that temperature for duration of 30 seconds to desorb the oxide on the silicon surface and subjected to an arsenic flux while ramping down the temperature to approximately 400° C. A CdTe nucleation layer 1410 was deposited for approximately two minutes at a temperature of between approximately 420° C. and approximately 470° C., preferably 440° C. The as-grown layer was then desorbed by ramping the temperature to between approximately 660° C. and 710° C., preferably 680° C., in approximately 20 minutes. An epilayer 1412 was grown (step 1318) at approximately a temperature between approximately 480° C. and approximately 540° C., preferably 510° C., for approximately 30 minutes. In the conventional growth process, the as-grown nucleation layer was not desorbed before the subsequent growth of the epilayer. Plan view SEM was used as an initial characterization step to observe the selectivity of CdTe on the islands. SEM images of the samples are shown in FIGS. 15A and 15B.

SEM data shows no CdTe growth on the silicon-dioxide growth mask 1414, which is indicative of the selectivity of CdTe to silicon vs. silicon dioxide. This high temperature process desorbs the CdTe deposited on the silicon islands and the polycrystalline material deposited on the silicon dioxide growth mask. However, since the bond energy between silicon and CdTe was higher than that of silicon dioxide and CdTe, all the polycrystalline material deposited on the silicon dioxide mask was desorbed at this temperature while some CdTe remains bonded to the silicon surfaces on the nanopillars 1416. When epilayer growth was subsequently performed, CdTe grows on top of the silicon islands, resulting in the selective growth of CdTe. To further characterize selectivity and the thickness of the CdTe obtained on the nanopillars. AFM images of the characterized samples are shown in FIG. 16.

AFM data for the sample (FIG. 16) shows CdTe a thickness of 46 nm. Other pitches showed a thickness of between 34 nm and 46 nm. It can be seen that the CdTe nucleated at the center of each island 1416 while the periphery of the island 1408 is devoid of CdTe, which was probably due to the high desorption rate of CdTe at the edges of the island.

X-ray diffraction (XRD) measurements were performed on the selective CdTe grown on the nanopatterned SOI substrates to analyze the crystallographic orientation of the CdTe. The ultimate goal of the selective epitaxy process was to obtain single crystalline CdTe on the nanopatterned SOI substrates. FIG. 17 shows the XRD results of the characterized samples.

X-ray diffraction data on the substrate shows distinctive peaks corresponding to the silicon (100) orientation and CdTe (111) orientation, which indicated that the selectively grown CdTe is single crystalline and had the orientation that is expected on Si (100) substrates. These results validate that the MBE growth technique can be used to achieve selective epitaxy of CdTe on patterned substrates and obtain single crystalline epitaxial material.

Following the selective growth of CdTe, we extended the epitaxy process to achieve lateral epitaxial overgrowth (LEO) 1320 of CdTe on the nanopillars. LEO is a technique that has been applied to various heteroepitaxial systems, especially III-V semiconductor materials, to reduce threading dislocation densities. LEO employs the growth of an epilayer from the window regions of growth mask patterned trenches. After the epilayer has reached the top of the trench, it was overgrown 1320 on the growth mask, thereby reducing the dislocation density. Finally, the overgrown regions coalesced 1320 to form a uniform layer 1412 upon which device fabrication can be performed. Example 5 provides more detail on the process conditions of the deposition.

### Example 5

CdTe was initially nucleated on nanopatterned compliant SOI substrates at a temperature of 440° C. It was then desorbed at a temperature of 680° C. for 5 minutes. After CdTe desorption producing CdTe-topped nanopillars 1416 as seen in FIG. 14C, an epilayer 1412 was grown at the higher temperature of 510° C. for 60 minutes. A schematic sectional view is shown in FIG. 14D. We observed that the CdTe grew selectively on the silicon nanoislands 1408 and then lateral overgrowth was obtained (even with a symmetric growth ratio) followed by coalescence of CdTe. The pitch between the nanoislands 1408 is of the order 500 nm. When the thickness of the grown CdTe 1412 reaches a scale comparable to the spacing between the nanoislands, it coalesced. Previous work on LEO of CdTe was performed on trenches 5 μm wide, which required significant lateral growth to achieve coalescence. In the case of nanopatterned substrates, we showed that it was possible to achieve coalescence even with the growth of a thin CdTe epilayer. The achieved coalescence is non-homogeneous in the images shown in FIGS. 17A and 17B at this time, as can be seen from the SEM images. This was probably due to the non-uniformity of temperature on different regions of the sample.

As with the first method, once the Group II-VI semiconductor layer 1420 has formed, the method may further comprise depositing 1322 at least one HgCdTe layer 1430 above the substrate for use in infrared photon detectors.

In another embodiment of the invention, the inventors teach a method of fabricating a Group II-VI semiconductor structure on a substrate that reduces stress within the semiconductor by patterning holes into the substrate. Thermal mismatch arises due to different coefficients of expansion of the various materials involved and increases the internal stress within the semiconductor. If the internal stresses become too high, the layers separate or crack.

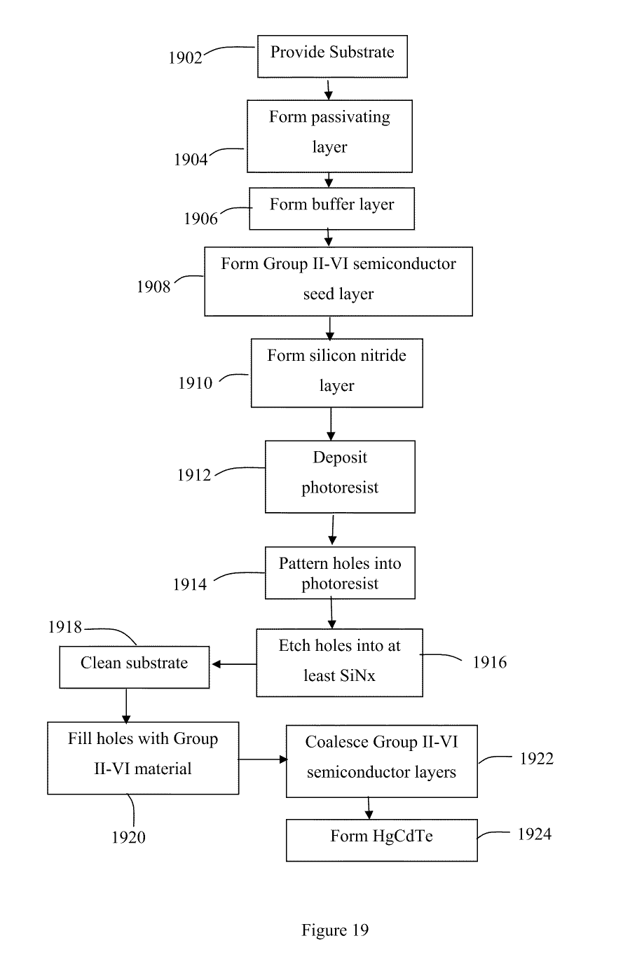

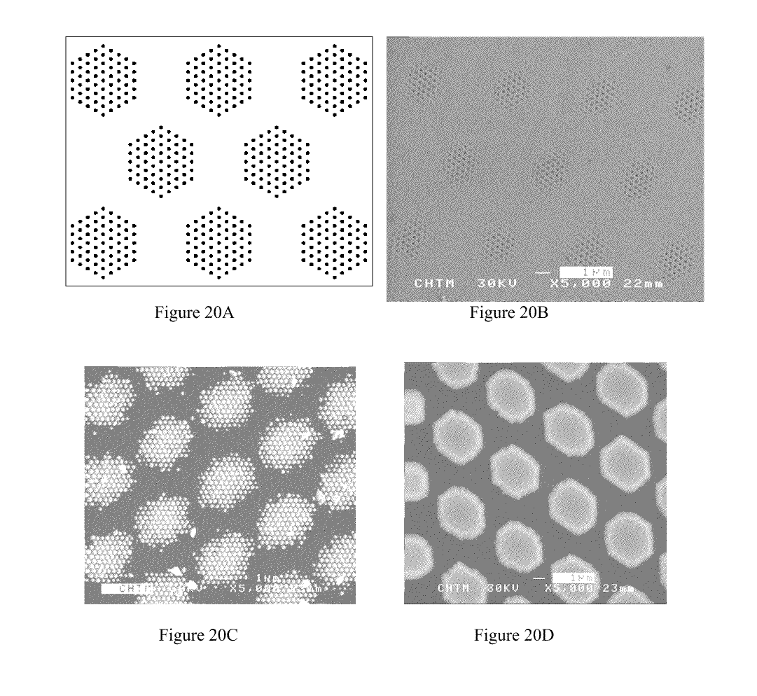

In the following discussion, reference is made to FIGS. 19 and 20A-D. Suitable substrates for the structure include silicon, SOI, and sapphire. After selecting (step 1902) a substrate, at least one silicon nitride layer is formed (step 1910) above the substrate. Several optional layers may be deposited as well. First, at least one passivation layer, preferably arsenic, may be deposited (step 1904) adjacent to the substrate. Second, at least one buffer layer, preferably ZnTe, may be deposited (step 1906) as well. Third, at least one Group II-VI semiconductor layer, preferably CdTe, may be deposited (step 1908) as well.

After deposition (step 1910) of the silicon nitride layer, at least one photoresist is deposited (step 1912) above the silicon nitride layer and a plurality of holes having at least one diameter is patterned (step 1914) into at least the photoresist layer. The pitches of the holes are at least approximately 100 nm and the diameters of the holes are diameters greater than 50 nm.

Patterning (step 1914) of the holes into the photoresist is done by interferometric lithography. The pattern is then etched into at least the silicon nitride layer 1916, preferably with a reactive ion etch or an inductively coupled plasma etch. The substrate may be cleaned (step 1918), preferably with oxygen plasma as discussed above to remove any remaining photoresist. At least one Group II-VI semiconductor layer, preferably CdTe, is then filled (step 1920), preferably by molecular beam epitaxy, into at least the plurality of holes. Preferably, the at least one Group II-VI semiconductor material coalesces (step 1922) to form at least one uniform layer. Finally, at least one additional layer of HgCdTe may be formed (step 1924) above the uniform layer.

As above, the step of depositing (step 1920) the Group II-VI semiconductor material may be a several step process. In the first step, a Group II-VI nucleation layer is deposited (part of step 1920) at a first temperature. Second, the temperature is ramped, or increased, (part of step 1920) to a second temperature, thereby desorbing the nucleation layer. Third, the temperature is decreased (part of step 1920) to a third temperature and at least one additional layer of Group II-VI semiconductor is then deposited (part of step 1920).

As shown in FIGS. 20A-20D, the plurality of holes may be arranged into one or more geometric shapes, or moirés, which may be spaced apart from each other as shown in FIGS. 20A and 20B. The shapes may be octagonal or hexagonal as shown in FIG. 20A and the distances between the shapes include distances of between approximately 2 μm to approximately 20 μm. The shapes may have a width of greater than approximately 3 μm across. Similar work has been done in Group II-V semiconductors, the results of which are shown in FIGS. 20C and 20D.

In another aspect of the invention, the process described above for the formation of uniform Group II-VI semiconductor layers may be used to form arrays of cells that act as pixels for infrared detectors. The nanoscale features in each pixel is a significant improvement over the prior art, since it provides greater detail and a large amount of redundancy in the system in the event of failure of a number of the pixels. As with the previous embodiments, at least one layer of infrared detection material, preferably HgCdTe, may be deposited above the uniform layer of Group II-VI semiconductor and may cover wavelengths from approximately 1 μm to approximately 30 μm.

While illustrated embodiments of the present invention have been described and illustrated in the appended drawings, the present invention is not limited thereto but only by the scope and spirit of the appended claims.

I claim:

1. A method for fabricating a compound semiconductor workpiece, comprising the steps of:
providing at least one substrate made from a material other than a Group II-VI semiconductor;
growing a Group II-VI semiconductor seed layer to be disposed above the substrate;
depositing a photoresist layer on the Group II-VI seed layer;
patterning a plurality of spaced-apart islands into the photoresist layer, the islands having a pitch in the range of about 100 nm to about 1000 nm;
etching the Group II-VI seed layer to create Group II-VI semiconductor islands using the photoresist layer as a mask; and
selectively forming at least one additional Group II-VI semiconductor layer on the Group II-VI semiconductor islands.

2. The method of claim 1, and further comprising the step of:
responsive to said step of forming at least one additional Group II-VI semiconductor on the Group II-VI semiconductor islands, coalescing the islands to form a uniform epilayer.

3. The method of claim 1, further comprising the step of annealing the seed layer.

4. The method of claim 1, further comprising the step of depositing a passivating layer above the substrate prior to growing the Group II-VI seed layer.

5. The method of claim 4, wherein the passivating layer comprises As.

6. The method of claim 1, further comprising the step of:
prior to said step of growing the Group II-VI seed layer, depositing at least one buffer layer to be disposed above the substrate, remote from the substrate.

7. The method of claim 6, wherein the buffer layer comprises ZnTe.

8. The method of claim 1, wherein the Group II-VI semiconductor is CdTe.

9. The method of claim 1, wherein the step of patterning islands into the photoresist layer is performed by interferometric lithography.

10. The method of claim 1, wherein the step of etching islands into the Group II-VI seed layer is an inductively coupled plasma etch.

11. The method of claim 1, wherein the additional Group II-VI semiconductor is grown on the islands by molecular beam epitaxy.

12. The method of claim 1, further comprising forming at least one infrared detection layer above the Group II-VI seed layer to be remote from the substrate.

13. The method of claim 12, wherein the at least one infrared detection layer is HgₓCd₁₋ₓTe, 0<x<1.

14. The method of claim 1, wherein said step of selectively forming includes the step of desorbing tellurium dioxide from the surface of the Group II-VI islands prior to selectively forming at least one additional Group II-VI semiconductor layer on the Group II-VI semiconductor islands.

15. The method of claim 1, further comprising: prior to said step of forming the seed layer, forming an antireflective coating.

16. The method of claim 1, further comprising implanting arsenic or forming at least one contact.

17. The method of claim 1, wherein each Group II-VI semiconductor island has a diameter between approximately 20 and approximately 500 nanometers

18. The method of claim 1, wherein the Group II-VI semiconductor islands are formed in a two-dimensional array.

19. A method of fabricating a Group II-VI semiconductor workpiece, comprising the steps of:
providing at least one substrate material made from a material other than a Group II-VI semiconductor;
forming at least one antireflective coating onto the substrate;
forming a photoresist layer above the substrate;
patterning the photoresist layer to leave spaced-apart islands of photoresist on the antireflective coating, the islands having a pitch in the range of about 100 nm to about 1000 nm;
etching the antireflective coating and substrate to leave islands of substrate, antireflective coating, and photoresist, each island having a lower end proximate to the substrate and an upper end remote from the substrate; and
selectively forming at least one Group II-VI semiconductor layer on the islands.

20. The method of claim 19, responsive to said step of depositing Group II-VI semiconductor on the islands, coalescing the islands to form a uniform layer.

21. The method of claim 19, wherein the step of selectively forming at least one Group II-VI semiconductor layer on the islands comprises:
growing a Group II-VI nucleation layer at the highest nucleation temperature for the Group II-VI semiconductor on silicon;
increasing the temperature to a second temperature above the highest nucleation temperature for the Group II-VI semiconductor on silicon, thereby desorbing the nucleation layer from locations other than on the Group II-VI semiconductor islands;
decreasing the second temperature to a third temperature below the highest nucleation temperature of the Group II-VI semiconductor on the Group II-VI seed layer, but above the highest nucleation temperature for the Group II-VI semiconductor on silicon; and
selectively forming Group II-VI semiconductor on the islands.

22. The method of claim 21, wherein the first temperature is from approximately 420° C. to approximately 470° C., the second temperature is from approximately 660° C. to approximately 710° C., and the third temperature is from approximately 480° C. to approximately 540° C.

23. The method of claim 19, wherein the substrate is a silicon on insulator (SOI) substrate.

24. The method of claim 23, wherein before selectively forming at least one Group II-VI semiconductor layer on the islands, the lower ends of the islands are silicon dioxide and the upper ends of the islands are silicon.

25. The method of claim 19, wherein the at least one Group II-VI semiconductor layer is CdTe.

26. The method of claim 19, wherein the antireflective coating has a thickness of approximately 150-160 nm.

27. The method of claim 19, further comprising depositing at least one HgₓCd₁₋ₓTe layer above the substrate, 0<x<1.

28. A compound semiconductor workpiece, comprising:
at least one substrate material made from a material other than a Group II-VI semiconductor; and
a plurality of spaced-apart islands formed from a Group II-VI semiconductor seed layer, each island having a lower end proximate to the substrate and an upper end remote from the substrate;
wherein the islands are on a pitch of from approximately 100 to approximately 1000 nm.

29. The workpiece of claim 28, further comprising at least one additional Group II-VI semiconductor layer selectively formed on the islands.

30. The workpiece of claim 28, wherein the substrate comprises Si.

31. The workpiece of claim 30, wherein the substrate is a silicon on insulator substrate.

32. The workpiece of claim 29, wherein the at least one additional Group II-VI semiconductor layer has coalesced to form a uniform layer.

33. The workpiece of claim 28, wherein the islands are on a pitch of from approximately 250 to approximately 500 nm.

34. The workpiece of claim 28, wherein each island is approximately from 20 nm to approximately 500 nm in diameter.

35. The workpiece of claim 34, wherein each island is approximately 20 nm to approximately 300 nm in diameter.

36. The workpiece of claim 28, wherein each island has a height of approximately 15 nm to approximately 500 nm.

37. The workpiece of claim 28, wherein the islands are formed in a two dimensional array.

38. The workpiece of claim 28, further comprising a passivation layer.

39. The workpiece of claim 28, wherein the passivation layer comprises As.

40. The workpiece of claim 28, further comprising at least one buffer layer disposed to be above and remote from the substrate.

41. The workpiece of claim 40, wherein the buffer layer comprises ZnTe.

42. The workpiece of claim 28, wherein the Group II-VI semiconductor seed layer is CdTe.

43. The workpiece of claim 28 further comprising least one HgₓCd₁₋ₓTe layer above the Group II-VI seed layer disposed to be remote from the substrate, 0<x<1.

44. A compound semiconductor workpiece comprising:
a substrate made of a material other than Group II-VI semiconductor material; and
a monolithic layer of Group II-VI semiconductor material disposed above the substrate, the layer having a number of dislocations which is less than or equal to approximately 5×10⁵/cm².

45. The workpiece of claim 44, wherein the substrate is selected from the group consisting of silicon and silicon on insulator.

46. The workpiece of claim 44, wherein the monolithic layer of Group II-VI semiconductor material is CdTe.

47. The workpiece of claim 44, further comprising least one HgₓCd₁₋ₓTe layer above the Group II-VI seed layer disposed to be remote from the substrate, 0<x<1.

48. A semiconductor device comprising:
a substrate made of a material other than Group II-VI semiconductor material; and
a monolithic layer of Group II-VI semiconductor material disposed above the substrate, the layer having a number of dislocations which is less than or equal to approximately 5×10⁵/cm².

49. The workpiece of claim 48, wherein the substrate is selected from the group consisting of silicon and silicon on insulator.

50. The workpiece of claim 48, wherein the monolithic layer of Group II-VI semiconductor material is CdTe.

51. The workpiece of claim 48, further comprising least one HgₓCd₁₋ₓTe layer above the Group II-VI seed layer disposed to be remote from the substrate, 0<x<1.

52. A method of fabricating a compound semiconductor workpiece, comprising the steps of:
providing at least one substrate material having an upper face of elemental silicon semiconductor;
forming a silicon nitride layer on the upper face of the substrate;
depositing at least one photoresist layer above the silicon nitride layer;
patterning a plurality of holes into the photoresist layer, the holes having a pitch in the range or about 100 nm to about 1000 nm;
etching the holes in at least the silicon nitride layer; and
filling at least the plurality of holes with Group II-VI semiconductor material.

53. The method of claim 52, further comprising the step of coalescing the Group II-VI semiconductor material formed in the holes to form a uniform Group II-VI layer.

54. The method of claim 52, wherein the etching of the photoresist layer is performed by using an interferometric lithography etch.

55. The method of claim 52, wherein the etching of the silicon nitride layer is performed by using a reactive ion etch.

56. The method of claim 52, further comprising:
prior to filling at least the plurality of holes with a Group II-VI semiconductor material, forming at least one passivating layer to adjoin the substrate.

57. The method of claim 56, wherein the at least one passivating layer is arsenic.

58. The method of claim 52, further comprising:
prior to filling at least the plurality of holes with a Group II-VI semiconductor material, forming at least one buffer layer to adjoin the Group II-VI semiconductor material.

59. The method of claim 58, wherein the at least one buffer layer is ZnTe.

60. The method of claim 52, wherein said step of filling the holes with at least one Group II-VI semiconductor is performed by molecular beam epitaxy.

61. The method of claim 52, wherein the step of filling the holes with at least one Group II-VI semiconductor further comprises:
forming a Group II-VI nucleation layer at a first temperature;
increasing the first temperature to a second temperature, thereby desorbing the nucleation layer in regions other than those in contact with the silicon nitride layer, having a plurality of nucleation sites;
decreasing the second temperature to a third temperature; and
growing further Group II-VI semiconductor material on the nucleation sites.

62. The method of claim 52, wherein the substrate is selected from the group consisting of silicon and SOI.

63. The method of claim 53, further comprising forming at least one layer of HgₓCd₁₋ₓTe on the uniform Group II-VI layer.

64. The method of claim 52, wherein the plurality of holes are etched in a two-dimensional pattern to relieve thermal mismatch between the substrate and the uniform Group II-VI layer.

65. The method of claim 64, wherein the pattern is at least one geometric shape.

66. The method of claim 65, wherein there are at least two geometric shapes of holes spaced between approximately 2 μm to approximately 20 μm apart.

67. The method of claim 65, wherein the at least one shape is greater than approximately 3 μm across.

68. The method of claim 65, wherein the geometric shape is a hexagon.

69. A compound semiconductor workpiece, comprising:
at least one substrate material having an upper face of elemental silicon;
at least one silicon nitride layer grown on the upper face of the substrate;
a plurality of spaced-apart holes etched into at least the silicon nitride layer to exposed the face of the substrate, the holes having a pitch in the range of about 100 nm to about 1000 nm; and
at least one Group II-VI semiconductor grown in the plurality of holes.

70. The workpiece of claim 69, wherein each hole has a diameter which is at least approximately 50 nm.

71. The workpiece of claim 69, wherein the substrate is selected from the group consisting of silicon and silicon on insulator substrates.

72. The workpiece of claim 69, further comprising at least one passivating layer adjoining the substrate.

73. The workpiece of claim 72, wherein the at least one passivating layer is arsenic.

74. The workpiece of claim 69, further comprising at least one buffer layer adjoining the Group II-VI semiconductor material.

75. The workpiece of claim 74, wherein the at least one buffer layer is ZnTe.

76. The workpiece of claim 69, further comprising at least one layer of HgₓCd₁₋ₓTe, 0<x<1, grown on said at least one Group II-VI semiconductor.

77. The workpiece of claim 69, wherein the at least one Group II-VI semiconductor layer is CdTe.
